(19) United States
(12) Patent Application Publication
(10) Pub. No.: US 2024/0063249 A1
(43) Pub. Date: Feb. 22, 2024

(54) METHOD OF MANUFACTURING PHOTO DETECTOR

(71) Applicant: Sumitomo Electric Industries, Ltd., Osaka (JP)

(72) Inventor: Takeshi OKADA, Osaka-shi (JP)

(73) Assignee: Sumitomo Electric Industries, Ltd., Osaka (JP)

(21) Appl. No.: 18/208,996

(22) Filed: Jun. 13, 2023

(30) Foreign Application Priority Data
Aug. 17, 2022 (JP) 2022-130146

(51) Int. Cl. H01L 27/146

(52) U.S. Cl. CPC H01L 27/14698; H01L 27/14649; H01L 27/1462; H01L 27/14636; H01L 27/14685; H01L 27/14694

(57) ABSTRACT

A method of manufacturing a photo detector includes preparing a substrate having a first main surface and a second main surface opposite to the first main surface, forming a semiconductor layer on the first main surface, forming a passivation layer having an opening on the semiconductor layer, forming an electrode on the semiconductor layer exposed through the opening, bringing the passivation layer into contact with an etchant after the electrode is formed, and inspecting characteristics after the bringing into contact with an etchant. In the method, the etchant has a higher etching rate for the semiconductor layer than the passivation layer.

### CROSS REFERENCE TO RELATED APPLICATIONS

This application claims priority based on Japanese Patent Application No. 2022-130146, filed on Aug. 17, 2022, the entire contents of which are incorporated herein by reference.

### TECHNICAL FIELD

The present disclosure relates to a method of manufacturing a photo detector.

### BACKGROUND

As a photo detector that detects near-infrared light, there is a photodiode in which a III-V group compound semiconductor is used in a light receiving layer that absorbs near-infrared light, and for example, a mesa-type photodiode in which a mesa is formed is disclosed (see, for example, Japanese Patent Application Laid-Open No. 2021-34644). The light receiving layer is covered with, for example, a passivation layer.

### SUMMARY

A method of manufacturing a photo detector according to the present disclosure includes preparing a substrate having a first main surface and a second main surface opposite to the first main surface, forming a semiconductor layer on the first main surface, forming a passivation layer having an opening on the semiconductor layer, forming an electrode on the semiconductor layer exposed through the opening, bringing the passivation layer into contact with an etchant after the electrode is formed, and inspecting characteristics after the bringing into contact with an etchant, wherein the etchant has a higher etching rate for the semiconductor layer than the passivation layer.

### BRIEF DESCRIPTION OF THE DRAWINGS

FIG. 1 is a cross-sectional view illustrating a photo detector according to an embodiment.

FIG. 2 is a cross-sectional view (part 1) illustrating a method of manufacturing a photo detector according to an embodiment.

FIG. 3 is a cross-sectional view (part 2) illustrating a method of manufacturing a photo detector according to an embodiment.

FIG. 4 is a cross-sectional view (part 3) illustrating a method of manufacturing a photo detector according to an embodiment.

FIG. 5 is a cross-sectional view (part 4) illustrating a method of manufacturing a photo detector according to an embodiment.

FIG. 6 is a cross-sectional view (part 5) illustrating a method of manufacturing a photo detector according to an embodiment.

FIG. 7 is a cross-sectional view (part 6) illustrating a method of manufacturing a photo detector according to an embodiment.

FIG. 8 is a cross-sectional view (part 7) illustrating a method of manufacturing a photo detector according to an embodiment.

FIG. 9 is a cross-sectional view (part 8) illustrating a method of manufacturing a photo detector according to an embodiment.

FIG. 10 is a cross-sectional view (part 9) illustrating a method of manufacturing a photo detector according to an embodiment.

FIG. 11 is a cross-sectional view (part 10) illustrating a method of manufacturing a photo detector according to an embodiment.

FIG. 12 is a cross-sectional view (part 11) illustrating a method of manufacturing a photo detector according to an embodiment.

FIG. 13 is a top view of a two-dimensional array type photo detector according to an embodiment.

### DETAILED DESCRIPTION

In manufacturing of a photo detector, a defect such as a pinhole in a passivation layer reduces the reliability of the photo detector.

It is an object of the present disclosure to provide a method of manufacturing a photo detector that allows improvement in the reliability of the photo detector.

### Description of Embodiments of the Present Disclosure

First, embodiments of the present disclosure will be listed and described. In the description, like or corresponding elements are denoted by like reference numerals and redundant descriptions thereof will be omitted.

A method of manufacturing a photo detector according to an embodiment of the present disclosure includes preparing a substrate having a first main surface and a second main surface opposite to the first main surface, forming a semiconductor layer on the first main surface, forming a passivation layer having an opening on the semiconductor layer, forming an electrode on the semiconductor layer exposed through the opening, bringing the passivation layer into contact with an etchant after the electrode is formed, and inspecting characteristics after the bringing into contact with an etchant. In the method, the etchant has a higher etching rate for the semiconductor layer than the passivation layer. In this case, when the passivation layer has a defect such as a pinhole, the etchant reaches the semiconductor layer through the defect in the step of bringing a passivation layer into contact with an etchant, so that the semiconductor layer is etched. When the semiconductor layer is etched, an appearance and electrical characteristics of the photo detector are changed, so that an abnormality of the photo detector can be easily detected in the step of inspecting characteristics. On the other hand, when the passivation layer has no defect, the semiconductor layer is not etched because the etchant does not reach the semiconductor layer in the step of bringing a passivation layer into contact with an etchant. Therefore, the photo detector can be determined to be normal in the step of inspecting characteristics. As a result, the reliability of the photo detector can be enhanced.
(2) In the above (1), the step of bringing into contact with an etchant may include immersing the substrate in the etchant. In this case, since the first main surface and the second main surface come into contact with the etchant, it is possible to remove scratches and the like which may be generated when the second main surface is polished.
(3) In the above (1), the step of bringing into contact with the etchant may include applying the etchant onto the passivation layer. In this case, the etchant can be selectively brought into contact with only the first main surface. This is effective in a case where the second main surface is not desired to be etched.
(4) In any one of the above (1) to (3), the step of inspecting characteristics may include inspecting an appearance. In this case, an abnormality of the photo detector can be detected based on the appearance.
(5) In any one of the above (1) to (4), the step of inspecting characteristics may include inspecting electrical characteristics. In this case, an abnormality of the photo detector can be detected based on electrical characteristics.
(6) In any one of the above (1) to (5), the etchant may be hydrobromic acid. In this case, it is easy to selectively etch the semiconductor layer with respect to the passivation layer.
(7) In any one of the above (1) to (6), the method may further include polishing the second main surface after the step of forming an electrode, and the step of bringing into contact with an etchant may be performed after the step of polishing the second main surface and may include bringing the second main surface into contact with the etchant. In this case, it is possible to remove scratches and the like which may be generated when the second main surface is polished.
(8) In any one of the above (1) to (6), the method may further include forming an antireflection film on the second main surface after the step of forming an electrode, and the step of bringing into contact with the etchant may be performed after the step of forming an antireflection film. In this case, since the second main surface is covered with the antireflection film, the second main surface does not come into contact with the etchant. This is effective in a case where the second main surface is not desired to be etched.

### Details of Embodiments of Present Disclosure

Embodiments according to the present disclosure will be described below in detail, but the present disclosure is not limited thereto.

### (Photo Detector)

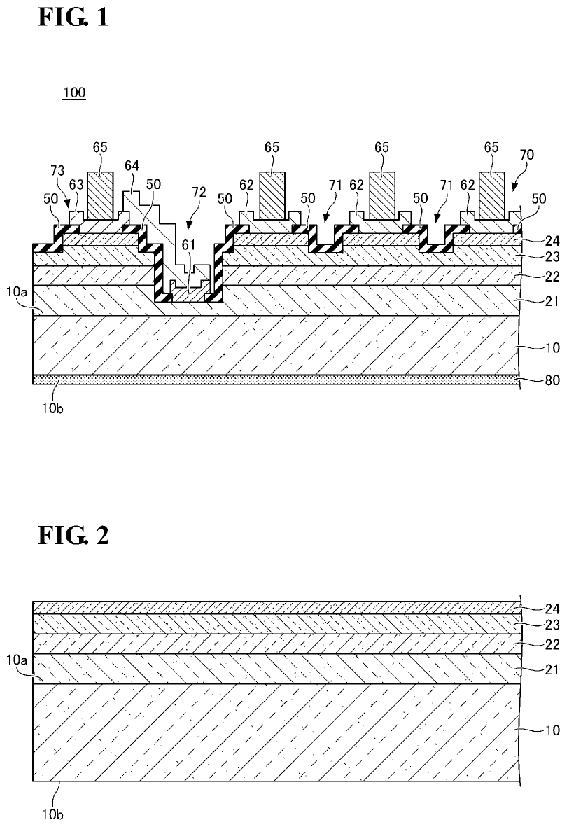

Referring to FIG. 1, a photo detector 100 according to an embodiment will be described. Photo detector 100 is a photo detector that detects near-infrared light. Photo detector 100 is a so-called rear-illuminated photo detector. As shown in FIG. 1, photo detector 100 includes a substrate 10.

Substrate 10 is, for example, an InP substrate. Substrate 10 is doped with iron (Fe) as an impurity element and is semi-insulating. Substrate 10 has a thickness of about 600 μm. Substrate 10 has a first main surface 10a and a second main surface 10b opposite to first main surface 10a. On first main surface 10a, an n-type contact layer 21, a light receiving layer 22, a wide gap layer 23, and a p-type contact layer 24 are provided in this order. An antireflection film 80 is provided on second main surface 10b. Antireflection film 80 is formed of, for example, an SiN film having a thickness of 150 nm.

N-type contact layer 21 is provided on substrate 10. N-type contact layer 21 is formed of n-InP and is doped with silicon (Si) as an n-type impurity element at a concentration of about 2×10¹⁸ cm⁻³.

Light receiving layer 22 is provided on n-type contact layer 21. Light receiving layer 22 is formed of undoped In_{0.53}Ga_{0.47}As.

Wide gap layer 23 is provided on light receiving layer 22. Wide gap layer 23 includes, for example, an n-type wide gap layer and a p-type wide gap layer. The n-type wide gap layer is formed of n-InP and doped with Si as an n-type impurity element at a concentration of about 2×10¹⁵ cm⁻³. The p-type wide gap layer is formed of p-InP and doped with Zn as a p-type impurity element at a concentration of about 2×10¹⁵ cm⁻³. A p-n junction is formed at an interface between the n-type wide gap layer and the p-type wide gap layer.

P-type contact layer 24 is provided on wide gap layer 23. P-type contact layer 24 is formed of p-InGaAs and doped with Zn as a p-type impurity element at a concentration of about 1×10¹⁹ cm⁻³.

A first groove 71 for pixel separation and a second groove 72 for exposing n-type contact layer 21 are formed in photo detector 100.

First groove 71 is formed by removing portions of p-type contact layer 24 and wide gap layer 23. First groove 71 has a depth of about 0.7 Wide gap layer 23 is exposed at a bottom surface of first groove 71. Each pixel is formed of mesa 70 separated by first groove 71. A p-electrode 62 is formed on p-type contact layer 24 in mesa 70. P-electrode 62 is formed of, for example, a layered film including a titanium (Ti) film having a thickness of about 50 nm and a platinum (Pt) film having a thickness of about 80 nm. A passivation layer 50 is provided on an exposed portion of a top surface of p-type contact layer 24, an exposed portion of wide gap layer 23 at the bottom surface of first groove 71, and exposed lateral faces of wide gap layer 23 and p-type contact layer 24 in first groove 71. A lateral face of the p-n junction of wide gap layer 23 is in contact with passivation layer 50. Passivation layer 50 is formed of, for example, an SiN film having a thickness of about 0.2 μm.

Second groove 72 is formed by portions of removing p-type contact layer 24, wide gap layer 23, light receiving layer 22, and n-type contact layer 21. Second groove 72 is formed along an outer periphery of photo detector 100. Second groove 72 has a depth of about 6 μm. N-type contact layer 21 is exposed at a bottom surface of second groove 72. An n-electrode 61 is formed on an exposed portion of n-type contact layer 21. N-electrode 61 is formed of, for example, a layered film including a Ti film having a thickness of about 50 nm and a Pt film having a thickness of about 80 nm.

A wiring electrode 63 is provided on p-type contact layer 24 in mesa 73 at the outer periphery separated by second groove 72. Wiring electrode 63 is formed of, for example, a layered film including a Ti film having a thickness of 50 nm and a Pt film having a thickness of about 80 nm. Wiring electrode 63 is electrically connected to n-electrode 61 by a wiring line 64. Wiring line 64 is formed of, for example, a layered film including a Ti-film having a thickness of about 50 nm and an Au-film having a thickness of about 600 nm. Passivation layer 50 is provided on a portion of n-type contact layer 21 exposed at the bottom surface of second groove 72, and exposed lateral faces of n-type contact layer 21, light receiving layer 22, wide gap layer 23, and p-type contact layer 24 in second groove 72.

An In-bump 65 is provided on each of p-electrode 62 and wiring electrode 63. In-bump 65 has a height of, for example, about 10 μm. For example, under bump metals (UBMs) (not shown) may be provided between p-electrode 62 and In-bump 65, and between wiring electrode 63 and In-bump 65. Each of the under bump metals is formed of, for example, a layered film including a Ti film having a thickness of 50 nm, a Ni film having a thickness of 100 nm, and an Au film having a thickness of 30 nm.

### (Method of Manufacturing a Photo Detector)

A method of manufacturing photo detector 100 according to an embodiment will be described with reference to FIGS. 2 to 13.

First, as shown in FIG. 2, n-type contact layer 21, light receiving layer 22, wide gap layer 23, and p-type contact layer 24 are formed in this order on first main surface 10a of substrate 10 by epitaxial growth.

Substrate 10 is, for example, an InP substrate. Substrate 10 is doped with Fe (iron) as an impurity element and is semi-insulating. Substrate 10 has a thickness of about 600 μm.

N-type contact layer 21 is formed of n-InP and doped with Si as an n-type impurity element at a concentration of about 2×10¹⁸ cm⁻³.

Light receiving layer 22 is formed of undoped In_{0.53}Ga_{0.47}As.

Wide gap layer 23 includes, for example, an n-type wide gap layer and a p-type wide gap layer. The n-type wide gap layer is formed of n-InP and doped with Si as an n-type impurity element at a concentration of about 2×10¹⁵ cm⁻³. P-type wide gap layer is formed of p-InP and doped with Zn as a p-type impurity element at a concentration of about 2×10¹⁵ cm⁻³. A p-n junction is formed at an interface between the n-type wide gap layer and the p-type wide gap layer.

P-type contact layer 24 is formed of p-InGaAs and doped with Zn as a p-type impurity element at a concentration of about 1×10¹⁹ cm⁻³.

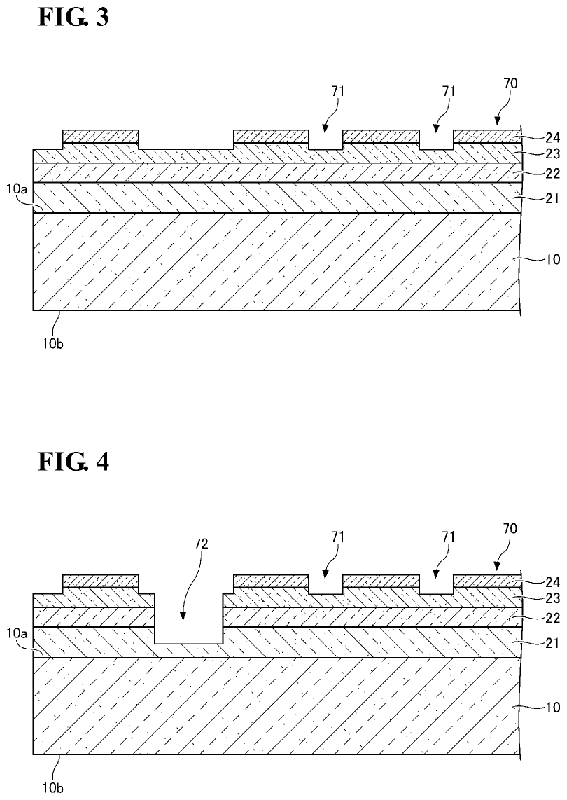

Next, as shown in FIG. 3, first groove 71 is formed for pixel separation. Specifically, an SiN film (not shown) is formed on p-type contact layer 24 by plasma chemical vapor deposition (CVD). Thereafter, a photoresist is applied onto the formed SiN film, and exposure and development are performed with an exposure apparatus to form a resist pattern (not shown). The resist pattern has an opening in a region where first groove 71 is to be formed. The SiN film in the opening of the resist pattern is removed by wet etching using buffered hydrofluoric acid to form a mask of the SiN film. Thereafter, the resist pattern (not shown) is removed by an organic solvent or the like. Thereafter, p-type contact layer 24 and wide gap layer 23 in a region from which the SiN film has been removed are partially removed by dry etching such as reactive ion etching (RIE) to form first groove 71. Thereafter, the SiN film (not shown) is removed by buffered hydrofluoric acid.

First groove 71 has a depth of about 0.7 μm. Wide gap layer 23 is exposed at a bottom surface of first groove 71. Each pixel is formed of mesa 70 separated by first groove 71.

Next, as shown in FIG. 4, second groove 72 is formed along an outer periphery to expose n-type contact layer 21. Specifically, an SiN film (not shown) is formed on p-type contact layer 24 and the like by plasma CVD. Thereafter, a photoresist is applied onto the formed SiN film, and exposure and development are performed with an exposure apparatus to form a resist pattern (not shown). The resist pattern has an opening in a region where second groove 72 is to be formed. The SiN film in the opening of the resist pattern is removed by wet etching using buffered hydrofluoric acid to form a mask of the SiN film. Thereafter, the resist pattern (not shown) is removed by an organic solvent or the like. Thereafter, wide gap layer 23, light receiving layer 22, and n-type contact layer 21 in a region from which the SiN film has been removed are partially removed by dry etching such as RIE to form second groove 72. Thereafter, the SiN film (not shown) is removed by buffered hydrofluoric acid.

Second groove 72 has a depth of about 6 μm. N-type contact layer 21 is exposed at a bottom surface of second groove 72.

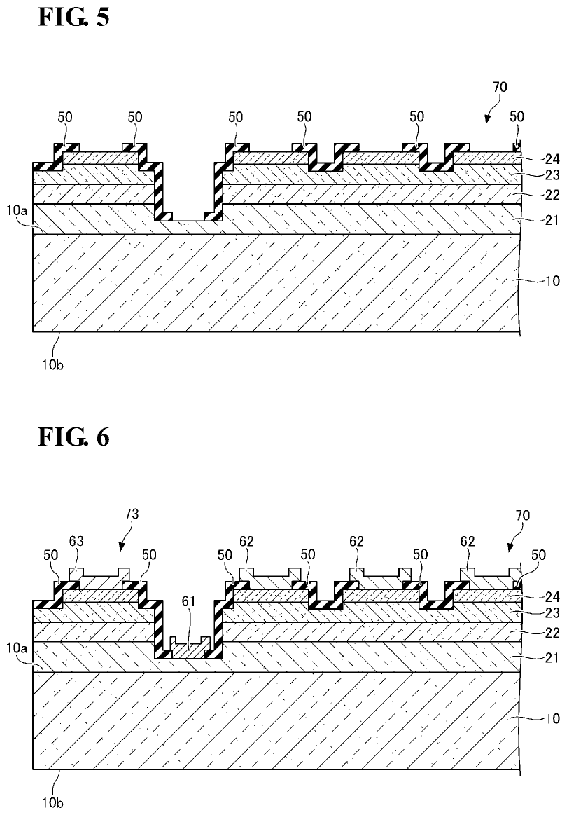

Next, as shown in FIG. 5, passivation layer 50 is formed. Specifically, passivation layer 50 is formed on the entire surface by plasma CVD. Thereafter, a photoresist is applied onto the formed passivation layer 50, and exposure and development are performed with an exposure apparatus to form a resist pattern (not shown). The resist pattern has openings in regions where n-electrode 61, p-electrode 62, and wiring electrode 63 are formed. Passivation layer 50 in the openings of the resist pattern is removed by dry etching such as RIE to form passivation layer 50 from which a top surface of p-type contact layer 24 and n-type contact layer 21 are exposed. Thereafter, the resist pattern (not shown) is removed by an organic solvent or the like. Passivation layer 50 is formed of, for example, an SiN film having a thickness of about 0.2 μm.

Next, as shown in FIG. 6, n-electrode 61 is formed on n-type contact layer 21. P-electrode 62 is formed on p-type contact layer 24 in mesa 70. Wiring electrode 63 is formed on p-type contact layer 24 in mesa 73 at the outer periphery. N-electrode 61, p-electrode 62, and wiring electrode 63 are formed by a lift-off method. Specifically, a resist pattern having openings in regions where electrodes are to be formed is formed, a metal film is formed by electron beam (EB) vapor deposition, and then the metal film on the resist pattern is removed together with the resist pattern by immersion in an organic solvent or the like. Each of n-electrode 61, p-electrode 62, and wiring electrode 63 is formed of, for example, a layered film including a Ti film having a thickness of about 50 nm and a Pt film having a thickness of about 80 nm.

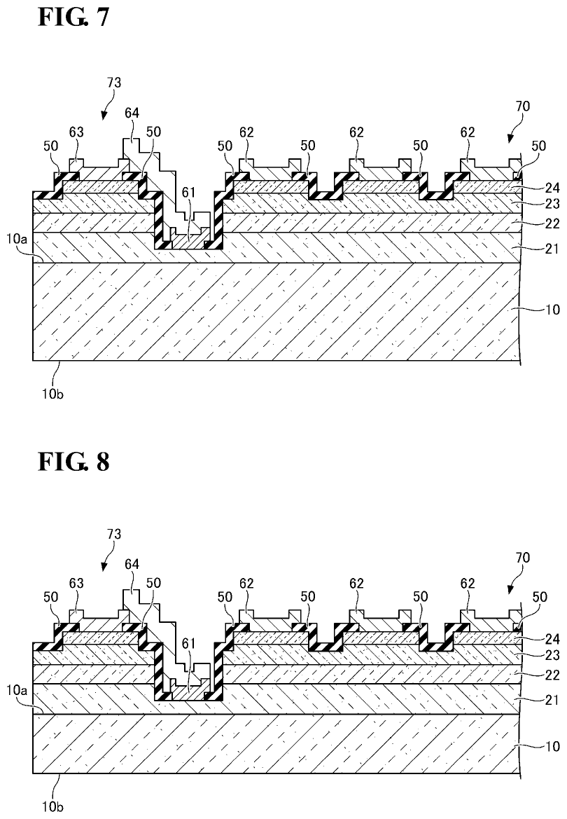

Next, as shown in FIG. 7, wiring line 64 for electrically connecting n-electrode 61 and wiring electrode 63 to each other is formed by a lift-off method. Wiring line 64 is formed of, for example, a layered film including a Ti-film having a thickness of about 50 nm and an Au-film having a thickness of about 600 nm.

Next, as shown in FIG. 8, second main surface 10b of substrate 10 is polished by chemical mechanical polishing (CMP). Substrate 10 has a thickness of about 550 μm after polishing.

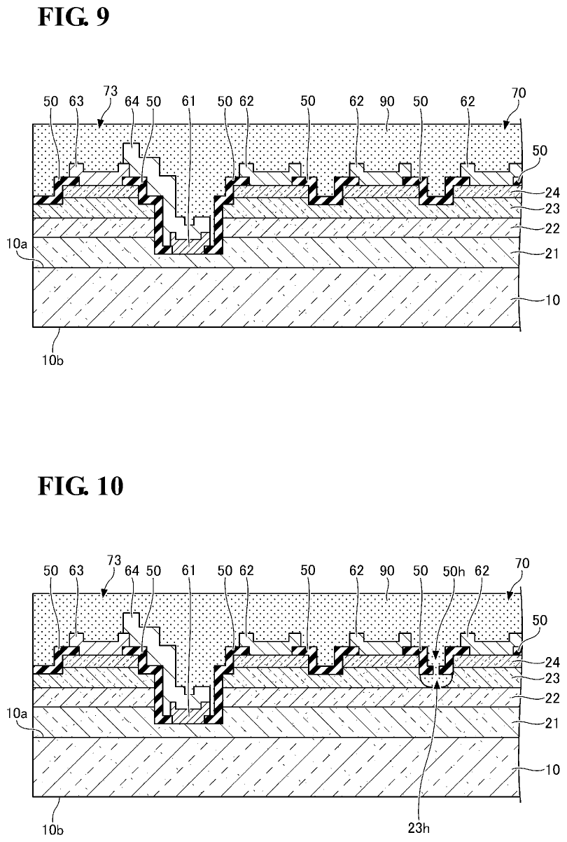

Next, as shown in FIG. 9, passivation layer 50 is brought into contacted with an etchant 90. Etchant 90 is a chemical solution that has a higher etching rate for n-type contact layer 21, light receiving layer 22, wide gap layer 23, and p-type contact layer 24 than for passivation layer 50. Etchant 90 may be, for example, hydrobromic acid. In this case, it is easy to selectively etch n-type contact layer 21, light receiving layer 22, wide gap layer 23, and p-type contact layer 24 with respect to passivation layer 50. Etchant 90 may be, for example, hydrochloric acid or a sulfuric acid-hydrogen peroxide mixture.

As shown in FIG. 9, when passivation layer 50 has no pinhole 50h, n-type contact layer 21, light receiving layer 22, wide gap layer 23, and p-type contact layer 24 that are covered by passivation layer 50 do not come into contact with etchant 90, thereby being not etched. On the other hand, as shown in FIG. 10, when passivation layer 50 covering wide gap layer 23 has a pinhole 50h, etchant 90 comes into contact with wide gap layer 23 through pinhole 50h, thereby etching wide gap layer 23. Therefore, a hole 23h is formed in a portion of wide gap layer 23 located immediately below pinhole 50h. Since wide gap layer 23 is etched isotropically, hole 23h having a diameter larger than that of pinhole 50h is formed in wide gap layer 23 when viewed in plan from a direction perpendicular to first main surface 10a. The same applies to a case where passivation layer 50 that covers n-type contact layer 21, light receiving layer 22, and p-type contact layer 24 has pinhole 50h.

When passivation layer 50 is brought into contact with etchant 90, for example, second main surface 10b may be brought into contact with etchant 90. In this case, it is possible to remove scratches and the like that may be generated during polishing of second main surface 10b. For example, immersing substrate 10 in a container filled with etchant 90 brings first main surface 10a and second main surface 10b into contact with etchant 90. In this case, it is possible to remove scratches and the like that may be generated during polishing of second main surface 10b. On immersing multiple substrates 10 in a container, for example, multiple substrates 10 may be stored in a substrate cassette made of fluororesin, and the substrate cassette may be immersed in the container filled with etchant 90. In this case, multiple substrates 10 can be processed at the same time, thereby improving productivity.

When passivation layer 50 is brought into contact with etchant 90, for example, etchant 90 may be applied onto passivation layer 50. In this case, etchant 90 can be selectively brought into contact with only first main surface 10a. This is effective in a case where second main surface 10b is not desired to be etched.

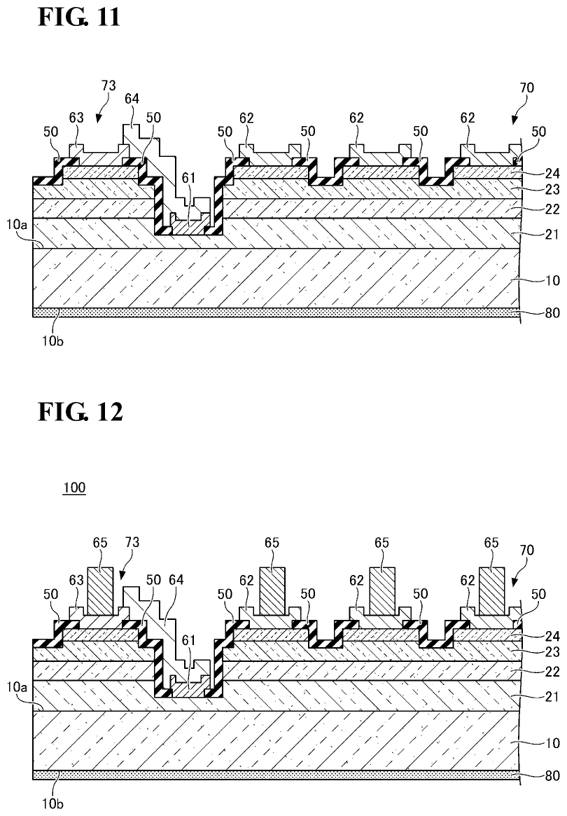

Next, as shown in FIG. 11, antireflection film 80 is formed on second main surface 10b of substrate 10. Specifically, antireflection film 80 is formed on the entire surface of second main surface 10b by plasma CVD. Antireflection film 80 is formed of, for example, an SiN film having a thickness of 150 nm.

Next, as shown in FIG. 12, In-bump 65 having a height of about 10 μm is formed on each of p-electrode 62 and wiring electrode 63 by a lift-off method. After under bump metals (not shown) are formed on p-electrode 62 and wiring electrode 63, In-bump 65 may be formed on each of the under bump metals. Each of the under bump metals is formed of, for example, a layered film including a Ti film having a thickness of 50 nm, a Ni film having a thickness of 100 nm, and an Au film having a thickness of 30 nm.

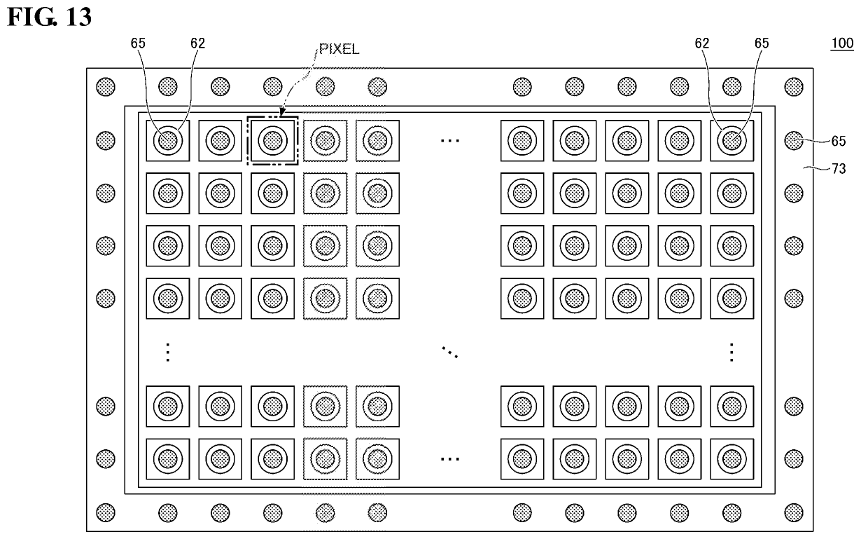

Next, substrate 10 is divided into multiple chips by dicing. Through the above steps, as shown in FIG. 13, a two-dimensional array type photo detector 100 in which pixels separated from each other by first groove 71 are two-dimensionally arranged is formed.

Next, characteristics of photo detector 100 are inspected. Specifically, an appearance of photo detector 100 is inspected with an appearance inspection apparatus including a camera or the like. In this case, an abnormality of photo detector 100 can be detected based on the appearance. As described above, in a case where passivation layer 50 covering wide gap layer 23 has pinhole 50h, when passivation layer 50 is brought into contact with etchant 90, hole 23h having a diameter larger than that of pinhole 50h is formed in wide gap layer 23. Therefore, product defects can be easily detected by inspecting the appearance of photo detector 100. On the other hand, when passivation layer 50 is not brought into contact with etchant 90, it is difficult to detect small pinhole 50h by the appearance inspection. The same applies to a case where passivation layer 50 that covers n-type contact layer 21, light receiving layer 22, and p-type contact layer 24 has pinhole 50h.

Further, electrical characteristics of photo detector 100 such as a dark current and the like are inspected with an electrical characteristics inspection apparatus including a current voltage source and the like. In this case, an abnormality of photo detector 100 can be detected based on electrical characteristics. As described above, when holes are formed in n-type contact layer 21, light receiving layer 22, wide gap layer 23, and p-type contact layer 24, desired electrical characteristics may not be obtained. For example, the dark current increases. Therefore, product defects can be easily detected by inspecting the electrical characteristics of photo detector 100. On the other hand, in a case where passivation layer 50 is not brought into contact with etchant 90, when pinhole 50h is small, no abnormality may be observed in initial electrical characteristics, and it is difficult to detect product defects by the inspection of the electrical characteristics.

As described above, in the method of manufacturing photo detector 100 according to the embodiment, characteristics of photo detector 100 are inspected after passivation layer 50 is brought into contact with etchant 90. In this case, when passivation layer 50 has pinhole 50h, etchant 90 comes into contact with semiconductor layers such as n-type contact layer 21, light receiving layer 22, wide gap layer 23, and p-type contact layer 24 through pinhole 50h to etch the semiconductor layers. When the semiconductor layers are etched, the appearance and electrical characteristics of photo detector 100 are changed, so that an abnormality of photo detector 100 can be easily detected in the step of inspecting characteristics. In particular, since photo detector 100 having poor long-term reliability can be removed, it is possible to prevent problems in the field. Therefore, the reliability of photo detector 100 can be enhanced. On the other hand, when passivation layer 50 does not have pinhole 50h, semiconductor layers covered by passivation layer 50 do not come into contact with etchant 90 and thus are not etched. Therefore, it is possible to determine that photo detector 100 is normal in the step of inspecting characteristics.

Although passivation layer 50 is brought into contact with etchant 90 after second main surface 10b is polished and before antireflection film 80 is formed on second main surface 10b in the above embodiment, the present disclosure is not limited thereto. For example, after antireflection film 80 is formed on second main surface 10b, passivation layer 50 may be brought into contact with etchant 90. In this case, since second main surface 10b is covered with antireflection film 80, second main surface 10b does not come into contact with etchant 90. This is effective in a case where second main surface 10b is not desired to be etched.

In the above embodiment, photo detector 100 is of a two-dimensional array type, but the present disclosure is not limited thereto. For example, photo detector 100 may be a photo detector in which pixels separated from each other by first groove 71 are one-dimensionally arranged.

The embodiments of the present disclosure have been described above. However, the present invention is not limited to the specific embodiments of the present disclosure, and various modifications and changes can be made within the scope of the claims.

What is claimed is:

1. A method of manufacturing a photo detector, the method comprising:
preparing a substrate having a first main surface and a second main surface opposite to the first main surface;
forming a semiconductor layer on the first main surface;
forming, on the semiconductor layer, a passivation layer having an opening;
forming an electrode on the semiconductor layer exposed through the opening;
bringing, after the electrode is formed, the passivation layer into contact with an etchant; and
inspecting, after the bringing into contact with an etchant, characteristics,
wherein the etchant has a higher etching rate for the semiconductor layer than for the passivation layer.

2. The method of manufacturing a photo detector according to claim 1,
wherein the bringing into contact with an etchant includes immersing the substrate in the etchant.

3. The method of manufacturing a photo detector according to claim 1,
wherein the bringing into contact with an etchant includes applying the etchant onto the passivation layer.

4. The method of manufacturing a photo detector according to claim 1,
wherein the inspecting characteristics includes inspecting an appearance.

5. The method of manufacturing a photo detector according to claim 1,
wherein the inspecting characteristics includes inspecting electrical characteristics.

6. The method of manufacturing a photo detector according to claim 1,
wherein the etchant is hydrobromic acid.

7. The method of manufacturing a photo detector according to claim 1, the method further comprising:
polishing, after the forming an electrode, the second main surface,
wherein the bringing into contact with an etchant is performed after the polishing the second main surface and includes bringing the second main surface into contact with the etchant.

8. The method of manufacturing a photo detector according to claim 1, the method further comprising:
forming, after the forming an electrode, an antireflection film on the second main surface,
wherein the bringing into contact with an etchant is performed after the forming an antireflection film.
